(19) United States
(12) Patent Application Publication
(10) Pub. No.: US 2025/0168969 A1
(43) Pub. Date: May 22, 2025

(54) SURFACE-TREATED COPPER FOIL FOR HIGH-FREQUENCY CIRCUIT AND METHOD FOR PRODUCING THE SAME

(71) Applicant: CIRCUIT FOIL LUXEMBOURG, WILTZ (LU)

(72) Inventors: Roman MICHEZ, Hollogne (BE); Michel STREEL, Houffalize (BE)

(21) Appl. No.: 18/832,557

(22) PCT Filed: Feb. 6, 2023
(86) PCT No.: PCT/EP2023/052872

§ 371 Date: Jul. 24, 2024

(30) Foreign Application Priority Data
Feb. 7, 2022 (LU) 501394

(51) Int. Cl. H05K 1/02; H05K 3/24; H05K 3/38

(52) U.S. Cl. CPC H05K 1/0242; H05K 3/244; H05K 3/384; H05K 3/389; H05K 2201/0335; H05K 2201/0338; H05K 2203/0392; H05K 2203/0723

(57) ABSTRACT

A surface treated copper foil for a High-Frequency circuit as well as a corresponding method of treating a copper foil, the copper foil including two opposite sides, where a first side is coated with a treatment layer including, in this order: a first layer including oxides of Mo and of Zn deposited on the first side, where the first layer is free of Ni; a second layer of Cr oxide; and a coupling agent layer; where the first layer includes the oxides of Mo and of Zn in a quantity of between 5 and 30 mg/m² calculated as Mo and Zn; where the treatment layer has a roughness Rz JIS of 0.7 μm or less; and where the first side is free of roughening treatment.

### TECHNICAL FIELD

The present disclosure relates to a surface-treated copper foil for a high-frequency circuit and more particularly relates to a surface-treated copper foil, which is excellent in adhesiveness with an insulating substrate for a high-frequency circuit and also excellent in transmission characteristics in a high-frequency region.

### BACKGROUND

Data is growing at an exponential rate and is not going to slow down, due to the popularization of information terminals like smartphones and laptops as well as social networking services and video-sharing platforms. This leads to increasing demands for transmitting massive data, which requires ever increasing signal transmission speeds between components on circuit boards. To achieve these speeds, frequency ranges are necessarily increasing from the MHz range to, 1 GHz, 10 GHz or even higher. In these higher ranges, the electrical currents flow mostly near the surface of the conductors due to the well-known “skin effect”, which is the tendency of high frequency current density to be highest at the surface of a conductor and to decay exponentially towards the center. The skin depth, where approximately 67% of the signal is carried, is inversely proportional to the square root of the frequency. Accordingly, at 1 MHz the skin depth is 65 μm, at 1 GHz it is 2.1 μm, while at 10 GHz the skin depth is only 0.65 μm.

At the higher frequencies, the surface topography or roughness of the conductor becomes ever more important since a roughness in the order of, or greater than, the skin depth will impact the signal transmission through scattering.

In this connection, it may be noted that in conventional printed circuit boards (PCBs), the surface of the conductor tracks is intentionally roughened to enhance adhesion characteristics to the resin layer used in the laminated PCB structures. A surface roughness, Rz, on the roughened surface in the order of several μm is typical and will impact any transmission in the GHz range. The conventional design is therefore constrained by the conflicting need for high roughness to ensure enough adhesion, and low roughness to minimize transmission loss. Conventional roughening treatments comprise the deposition of nodules (nodular treatment) on the copper foil surface; or attacking the surface of the copper by means of an acidic solution, thus forming a so-called brown-oxide.

A number of approaches have been developed to manufacture copper foils for HF applications. U.S. Pat. No. 10,772,199, JP S61 288095 A and EP 3 882 378 A1 disclose copper foils with microscale nodular treatment to ensure high bondability with the substrate.

US 2021/0321514 A1 suggests increasing the microroughness of the foils to ensure high bondability.

JP 6083619 B2 discloses a copper foil having a heat resistance treatment with a metallic content.

US2021029823 discloses a copper foil having an Adhesive layer for high signal transmission.

Despite various approaches proposed in the prior art, there still remains a need for copper foils with controlled properties for HF circuits, in particular the desired low transmission loss but also showing good adhesion, thermal resistance and chemical resistance.

### BRIEF SUMMARY

The present disclosure provides a surface treated copper foil for a High-Frequency circuit and a method of treating a copper foil.

According to the present disclosure, a surface treated copper foil comprises two opposite sides, wherein a first side is coated with a treatment layer comprising, in the following order:
a first layer comprising oxides of molybdenum and of zinc deposited on said first side, wherein said first layer is free of nickel;
a second layer of chromium oxide; and
preferably a coupling agent layer;

wherein the first layer comprises the oxides of molybdenum and of zinc in a quantity of between 5 and 30 mg/m² calculated as molybdenum and zinc;

wherein the surface treated copper foil has a roughness Rz JIS of no more than 0.7 μm; and

wherein the first side is free of roughening treatment.

The present disclosure proposes a surface treated copper foil that—according to first results—meets the requirements for application in high frequency circuits, particularly in terms of adhesion, heat resistance, chemical resistance and low transmission loss.

In other words, the present disclosure is based on the findings that the prescribed surface treatment directly applied onto the side of a copper foil, i.e. in the absence of any roughening treatment of the side of the copper foil, allows to minimize transmission losses at high frequency and to achieve the required low transmission loss for applications at frequencies of 1 GHz and above, such as for the Fifth-Generation of mobile communication (5G), without detrimental effect on the adhesion, heat resistance and chemical resistance of the surface treated copper foil.

This surprisingly goes against common practice in the field, wherein a roughening treatment is conventionally applied onto the copper foil to enhance its bondability and adhesion properties, as disclosed by JP S61 288095 A and EP 3 882 378 A1. However, such roughening treatment impacts the profile roughness of the foil and negatively impact signal integrity at high frequency.

On the contrary, the inventive copper foil being free of roughening treatment, signal transmission losses at high frequency are minimized.

Once again, it shall be appreciated that the low surface roughness of the treatment layer, reflecting the low surface roughness of the underlying copper foil induces lower signal loss in high speed/high frequency applications. This is due to the fact that at high frequency the signal is propagated only at the surface of the conductor (skin effect). On a smooth conductor the propagation route of the signal is therefore shorter, inducing lower loss. This enable the fabrication of effective transmission lines for applications at frequencies of 1 GHz and above (5G, etc.).

Surprisingly, the mechanical properties, and in particular the adhesion, of the surface treated copper foil were not negatively impacted by the absence of roughening treatment, due to the specific combination of the layers with prescribed composition forming the treatment layer.

In the present text, the term ‘roughening treatment’ is to be understood as a treatment designed to increase the roughness of a copper foil and that is applied to a copper foil after it has been removed from the electroplating cell in which it has been formed. In particular, the roughening treatment may refer to a nodular treatment i.e. the electrodeposition of fine copper nodules (also sometimes referred to as dendritic copper) on the base copper foil, or a so-called brown oxide treatment or black oxide treatment. During a brown/black oxide treatment, the surface of the copper foil is micro-etched to a depth of about 1-2 μm, in order to create microroughness on the copper surface and simultaneously convert superficial copper into a layer of an organo-metallic structure that will help for the adhesion.

The first layer comprises oxides of Mo and of Zn and provides a first passivation layer normally directly formed on one side of the copper foil. The first layer may be formed by an electrolytic co-deposition process. The first layer may include a variety of oxide forms (various oxidation states), namely oxides of Zn, oxides of Mo, or mixed oxide forms of Zn and Mo. In particular, the oxides may be formed which comprise at least one oxygen atom bound to Mo, resp. to Zn, at one or more oxidation states. Without willing to imply any limitation, first analyses have shown that the oxides contain, for zinc mainly Zn²⁺ and for molybdenum Mo⁶⁺, Mo⁵⁺ and/or Mo⁴⁺. Within the first layer, Mo allows improving heat resistance of the copper foil. Zn is used to permit the deposition of Mo, i.e. to operate co-deposition of Mo and Zn in an electrolytic cell. In other words, the first layer is mainly a layer of a binary alloy of Zn oxides and Mo oxides, including mixed oxides, where Zn and Mo may be found in one or several oxidation states.

The herein prescribed amounts of Mo and Zn for the first layer (expressed with respect to the element itself, i.e. Mo resp. Zn—not the oxide forms) are selected to provide good thermal resistance as well as high chemical resistance.

In embodiments, the weight ratio of Mo to Zn in said first layer is between 0.3 to 1.5.

The first layer is free of Ni. Indeed, Ni is not desired in the first layer and there is no voluntary Ni addition in the bath. Impurities or traces may however exist, typically not more than 0.2 mg/m².

Similarly, the first layer is preferably free of Co. Impurities or traces may however exist, typically not more than 0.05 mg/m².

Preferably, the first layer comprises more than 85 wt. % of oxides of Mo and of Zn, in particular more than 90 or 95 wt. %. Further to heat and chemical resistance, the use of oxide forms of Mo and of Zn, allows reducing insertion loss compared to the metallic forms (metallic passivation).

In some embodiments, the first layer may comprise a small amount of other metal(s), for example Cr, in particular in oxide forms.

The first layer may possibly comprise traces of species other than the desired Mo and Zn oxides that come from the electrolyte solution.

The second layer provides a second passivation, normally directly formed on the first layer. This second layer is provided to further improve the chemical stability of the first layer as well as prepare for the deposition of the coupling agent. The second layer may comprise 80 to 100 wt % of chrome oxide, in particular 95 to 100%. The second layer may include one or more oxides forms of Cr, in particular with Cr at oxidation state III and/or other oxidation state(s).

The third layer, i.e. the coupling agent layer, is normally formed directly on the second layer to provide desired adhesion property to the resin/polymer substrate during lamination. In that respect, it may be appreciated that the above-mentioned first and second layers, with their prescribed design, provide good adhesion to the third, coupling agent layer, which in turn provides adhesion to the resin/polymer substrate. This is of relevance since there is no roughening treatment to improve adhesion to the resin/polymer substrate.

The present surface treated copper foil has a very low surface roughness Rz JIS of 0.7 μm or less. The indicated roughness is that of the free surface of the treatment layer (i.e. the free surface of coupling agent layer, opposite the second layer).

It may be noted that the treatment layer does not substantially change the surface roughness of the copper foil side on which it is formed. In other words, each layer of the treatment layer tends to follow/reproduce the surface roughness of the underlying layer, and ultimately the one of the base copper foil. The functional layers of the treatment layer are rather thin layers that do not sensibly modify the surface roughness of the treated copper foil, which is mainly determined by the initial roughness of the base copper foil.

In embodiments, the treatment layer has a roughness Rz JIS of 0.6 μm or less, e.g. 0.5, or 0.4 μm. SDR of the treatment layer may be of 0.3% or less, in particular of 0.2 or 0.1% or less. It may be noted here that the treatment layer does essentially not change the roughness of the base copper layer.

It should be appreciated that such low SDR expresses the fact that the treatment layer is a smooth layer and that the copper foil does not include any roughening layer. Bondability/adhesion properties of the inventive surface treated copper foil is thus ensured by the treatment layer, in particular the third (coupling agent) layer.

In this context, it is believed that 3D parameters, and more particularly the surface developpe ratio (SDR), is more suitable for accurately characterizing the surface roughness of treated copper foils, in particular surface treated copper foils which may be used for high-frequency application and present low insertion loss, than two-dimensional (or 2D) surface parameters.

The surface developed ratio (SDR), or developed interfacial area ratio, sometimes also referred to as the complexity of the surface, corresponds to the ratio between the area of the real developed surface and the area of the projected surface. The real surface is the interfacial area of the surface treated copper foil while the projected surface is the surface of a corresponding flat, completely smooth foil. The SDR can be calculated based on the following equation (or equivalent computation):

$$S D R = \frac{Real developped surface - Projected surface}{Projected surface} \times 100$$

In other words, SDR is expressed as the percentage of additional surface area contributed by the texture (presence of peaks and valleys at the surface of the copper foil as well as copper nodules and/or filaments of dendritic copper) as compared to an ideal plane surface. As SDR is affected by both the texture (number and size of peaks and valleys, of nodules and/or of filaments of dendritic copper) and the spatial disposition thereof, this parameter advantageously further differentiates surfaces of similar roughness as expressed using 2D parameters, such as Rz. Typically, SDR will increase with the spatial intricacy of the texture, whether or not Rz changes.

In this regard, it should be noted that copper foils having been submitted to a roughening treatment, such as e.g. the electrodeposition of fine copper nodules or dendritic copper, might present a surface roughness as of Rz JIS similar to the one of a (surface treated) copper foil without any roughening treatment, while the SDR value would be much higher for a roughened (surface treated) copper foil.

Preferably, the copper foil on which the treatment layer is formed is an electrodeposited copper foil. The treatment layer is generally applied on the electrolyte side, but it can also be applied on the drum side. The side of the electrodeposited copper foil on which the treatment layer is formed is a low roughness side, having preferably a roughness Rz JIS of 0.7 μm or less, e.g. 0.6, 0.5 or 0.4 μm. The SDR of same side is normally 0.3% or less, in particular 0.2 or 0.1% or less. Preferably the second side of the copper foil, opposite the side with the treatment layer, has a surface roughness in the same range.

In summary, the present disclosure provides a surface treated copper foil containing a first layer of Zn and Mo oxides providing a first passivation with a non-metallic alloy, which has the advantage of improving the thermal resistance without impacting the signal integrity at high frequency.

Compared to prior art foils, the surface treatment of the inventive surface treated copper foil does not include any nodules/nodular treatment, nor any other kind of roughening treatment. Furthermore, the treatment layer has a very smooth roughness profile; the treatment layer does essentially not change the surface roughness of the copper foil side on which it is formed. It may be noted in that respect that the low surface roughness is reflected by the Rz and SDR values.

The present disclosure proposes a copper foil that is smooth to ensure low insertion loss at high frequencies, despite any roughening treatment, and which exhibits good performance having regard to criteria such as peel strength, chemical attack and blistering.

As a further benefit, the passivation on a smooth copper foil typically requires less material than a copper foil with nodules.

The present disclosure thus solves the problem of high transmission loss at high frequency by a surface treatment with the herein prescribed combination of layers, provided on a low roughness copper foil, with a non-metallic passivation and without nodular/roughening treatment.

According to another aspect, the present disclosure relates to a method of treating a copper foil, the method comprising:
providing a copper foil having two opposite sides;
coating a first side of the copper foil with a treatment layer, the coating comprising:
   in a first bath, electrodepositing a first layer of Mo and Zn oxides, the first bath comprising between 1.5 and 7 g/L of Mo and between 1 and 5 g/L of Zn, the first bath being free of Ni;
   in a second bath, electrodepositing a second layer of Cr oxides over the first layer;
   in a third bath, forming a coupling agent layer over the second layer.

The present method is adapted to provide a treatment layer on a copper foil as disclosed above. Technical features, explanations and advantages disclosed in relation to the herein disclosed surface treated copper foil apply mutatis mutandis to the present method.

The first bath may be an aqueous acidic solution comprising Mo and Zn in the prescribed amounts, or containing only Mo and Zn in addition to the acidic species (typically sulfuric acid or equivalent).

The first bath is free of Ni. Indeed, Ni is not desired in the first layer to be formed by the present method, and there is no voluntary addition of nickel in the bath. Impurities or traces may however exist, typically not more than 0.5 mg/m².

In embodiments, the first bath may comprise between 2.5 and 5.5 g/L of Mo and between 1.5 and 4 g/L of Zn. The first bath may have a pH between 3.0 and 4.5, preferably between 3.5 and 4.

The electrodeposition process in the first bath may be carried out using two distinct anodes applying different current densities. This allows a more flexible control of the co-deposition process. It may be noted that whereas Mo alone is difficult to deposit in aqueous solution, the present approach relying on co-deposition does provides a working solution to form a layer of oxides of Mo and of Zn. Hence the present disclosure contrasts with the state of the art where Mo has been co-deposited ferromagnetic elements such as Ni or Co, which have a negative effect at high frequencies.

The electrodeposition in the first bath is advantageously realized to form a first layer comprising the oxides of Mo and of Zn in a quantity of between 5 and 30 mg/m² calculated as Mo and Zn elements, preferably between 15 and 25 mg/m².

The second bath preferably comprising between 0.5 and 4 g/L of Cr, more preferably between 1 and 2 g/L. The second bath is typically an acidic solution (sulfuric acid) in which chromium oxide (e.g. CrO3) is added to meet the prescribed concentration. The second bath may have a pH between 1 and 4.

In embodiments, the electrodeposition process in the second bath is carried out such that the second layer comprises the oxides of Cr in a quantity of between 4 and 10 mg/m² calculated as Cr (not the oxide form).

In embodiments, the third bath comprises a functionalized silane coupling agent at a concentration between 0.5 and 5 wt. %, wherein said functionalized silane coupling agent preferably comprises an aminosilane, an epoxy-silane, vinyl-silane, methacrylate silane, or a mixture thereof.

Preferably, the third bath, in case of an aminosilane coupling agent, has a pH of 9 to 12, in particular about 10.5.

Prior to dipping in the first bath, the copper foil advantageously undergoes a cleaning step to remove any oxides, grease, etc. The cleaning step may e.g. involve dipping the copper foil in an acidic bath.

The side of the copper foil on which the treatment layer is formed has a surface roughness Rz JIS of 0.7 μm or less, in particular 0.6, 0.5 or 0.4 μm, or even less. Preferably both sides have a surface roughness in that range.

It may be noted that the process does not involve any nodular treatment, nor any other kind of roughening treatment of the surface of the copper foil onto which the treatment layer is formed. The process is conducted to have a smooth surface treated side. The surface treated copper foil has, measured from the exposed side of the treatment layer (i.e. the side not in contact with the copper foil), a roughness Rz JIS of 0.7 μm or less, in particular of 0.6, 0.5 or 0.4 μm or less.

According to another aspect, the disclosure relates to a copper clad laminate comprising a surface treated copper foil as disclosed herein laminated onto a substrate at 200° C. for 2 h. The substrate may generally be a polymer, in particular a resin or a prepreg. Such copper clad laminate exhibits following properties: the copper foil has a peel strength superior or equal to 0.40 N/mm, preferably at least 0.45 or 0.50 N/mm; a peel strength drop of 10% or less after a HCl test (chemical resistance); and is able to resist a blistering test (thermal resistance) at a temperature of 270° C., or 275° C. or more.

In the present context, any given numeric value covers a range of values from −10% to +10% of said numeric value, preferably a range of values form −5% to +5% of said numeric value, more preferably a range of values form −1% to +1% of said numeric value.

### BRIEF DESCRIPTION OF THE DRAWINGS

The present disclosure will now be described, by way of example, with reference to the accompanying drawings, in which:

FIG. 1: is a principle diagram of an embodiment of the present surface treated copper foil;

FIG. 2: is a principle diagram of a surface treatment line for implementing the present process; and

FIGS. 3 and 4: are XPS spectra of the treatment layer.

### DETAILED DESCRIPTION

The present disclosure addresses issues specific to copper foils for high-frequency circuits. Specifically, the disclosure provides in the following embodiments electrodeposited copper foils providing improved signal integrity at high frequency, by combining low roughness electrodeposited copper foil, roughening free treatment (in particular nodular free treatment) and metallic free passivation while ensuring high thermal and chemical resistance and high peel strength on PPE/PPO and PTFE material.

In conventional processes, low profile copper foils are treated with either microscale nodular treatments or roughening treatments to ensure high bondability to the substrate, impacting the signal transmission at high frequency.

Indeed, skin effect is experienced by resistors at high frequency. At low frequency, the distribution of the current is uniform throughout the resistor. However, as the frequency increases, the current distribution becomes non-uniform and is concentrated on the surface of the resistor. The current is confined only to the surface at RF frequency. At high frequency, alternative current has higher current density on the edges of the conductor and the current flows within the “skin depth”. Therefore, at these frequency ranges, signal integrity is mainly affected by the profile of the foils.

Losses of signal integrity at high frequency are therefore related to the high profile of the foil. Reduction of the profile of the foil will improve the signal integrity at high frequency, but can impact bondability. While some prior art processes involve the deposition of microscale nodular treatments or roughening treatments which impact the profile of the foil, the present process does not change or affect the profile of (basis) low roughness copper foil, while keeping boundary.

Improvements of the heat resistance is usually achieved by deposition of some metallic elements, such as Ni or Co, deposited in metallic state, which have a negative impact on signal integrity at high frequencies. While some patents are teaching the use of these elements to improve heat resistance, the present disclosure is only using an alloy in its non-metallic form which, does not negatively influence signal transmission at high frequency.

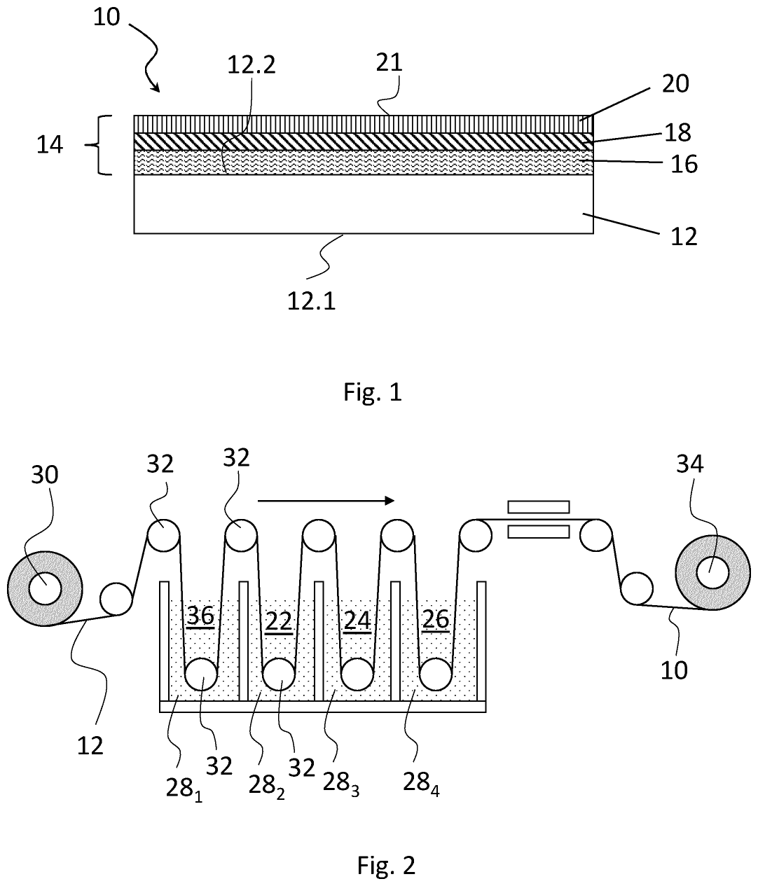

FIG. 1 schematically illustrates a surface treated copper foil 10 according to an embodiment of the present disclosure. It includes a copper foil 12, in particular an electrodeposited copper foil, having two opposite sides, namely a drum side 12.1 and an electrolyte side 12.2 (also referred to as matte side).

The electrolyte side 10.2 is coated with a treatment layer, generally indicated 14, that includes three layers:
a first layer 16 comprising oxides of Mo and of Zn;
a second layer 18 of chromate oxides; and
a third layer 20, referred to as coupling agent layer.

The first and second layers 14, 16 are passivation layers, whereas the third layer 18 is provided for improving adhesion to polymer/resin.

It may be noted that the three layers are, in practice, formed one after another on a side of the copper foil (so to speak one on top of another). Accordingly, they are herein described and represented as three separate layers. However, due to the small deposited amounts of material in each layer there may be somewhat intermingled.

The manufacture of the copper foil is not the purpose of the present disclosure. Any appropriate copper foil may be used. The copper foil is preferably an electrodeposited copper foil. Preferred characteristics of the copper foil are:
thickness in the range of 9 to 70 μm
roughness Rz JIS: drum side: 0.8-1.2 μm—electrolyte side: 0.4-0.7 μm
SDR: electrolyte side: <0.3%

Preferably, the foil has a copper purity of at least 99.8%. The tensile strength may typically be in the range of 31 to 38 kgf/mm².

The inventive surface treated copper foil 10 results from a specific combination of layers having prescribed compositions. It has good results in terms of heat resistance, peel strength, chemical resistance and exhibits low transmission loss.

### <Surface Treatment Process>

The present copper foil is obtained by submitting the foil to a treatment process comprising three baths 22, 24, 26 contained in separate recipients 28i—referred to as treaters, one for forming each of said layers 16, 18 and 20. The process is typically continuous, i.e. the copper foil is dipped in a continuous manner through the series of treaters 28. This is illustrated in FIG. 2. The untreated (as produced) copper foil 12 is unrolled from a support drum 30 and guided, by means of guide rolls 32, through the various treaters 28. The obtained surface treated copper foil 10 is finally rolled on a receiving drum 34.

During storage of the untreated copper foil 12, copper oxides may form locally. Accordingly, before forming the treatment layer, the copper foil 12 is preferably cleaned. This optional cleaning step may be carried out by dipping in an acidic bath 36 in first treater 28₁. The acidic bath 36 may comprise sulfuric acid at a concentration between 60 and 100 g/L.

The cleaned copper foil 12 then enters the second treater 18.2 containing the first, passivating bath 22. First bath 22 is an acidic solution comprising 1.5 to 7 g/L of Mo and 1 to 5 g/L of Zn. It may be prepared from Na₂MoO₄·2H₂O and ZnSO₄·7H₂O. Concentrations given herein for the various baths relate to the metal ions in the solution.

First bath 22 is an electroplating bath where Zn and Mo are co-deposited in oxide forms. Various oxide forms of Zn and Mo are deposited as well as possibly mixed oxides. Whereas deposition of Mo in aqueous solutions is difficult, the present approach based on co-deposition does allow forming a coherent layer of oxides of Zn and of Mo.

The pH may be adjusted by addition of sulfuric acid and/or sodium hydroxide to between 3.0 and 4.5. A pH greater than 4.5 tends to causes precipitation of Zn. At pH<3, lower Zn amounts are deposited.

This electrodeposition step is conducted such that the first layer comprises the oxides of Mo and of Zn in a quantity of between 5 and 30 mg/m². This specific mass is calculated in respect of the Zn and Mo metals only.

Preferably, two separate planar anodes are arranged in the bath, to which different current densities are applied. The current density at each anode is adjusted depending on the desired amount of Zn and Mo to be deposited and the ratio Zn/Mo. The current density may typically vary between 0.2 and 1.4 A/dm².

At the exit of treater 28.2 the copper foil is coated with the first layer 16 and enters the second bath 24 in treater 28.3. Second bath 24 is a chrome plating bath typically comprising a mixture of chromium trioxide (CrO₃) and sulfuric acid. The concentration of Cr in the bath may be between 0.5 and 4 g/L. The pH of this passivation bath is preferably adjusted to about 2.0. Current density may be around 2 to 6 A/dm².

Deposition may be carried out with one anode. The chromium oxide(s) layer 18, also referred to as chromate layer, is formed on the first layer 16.

Next the copper foil with the first layer 16 and second layer 18 enter the last treater 28.4 containing the third bath 26. Bath 26 is an aqueous solution comprising a coupling agent, in particular a functionalized silane coupling agent, such as e.g. an aminosilane, an epoxy-silane, vinyl-silane, methacrylate silane, or a mixture thereof. The pH of the bath 26 is adapted depending on the type of coupling agent. For example, bath 26 is a basic solution when comprising aminosilane.

The concentration of coupling agent in third bath 26 may be between 0.5 and 5 wt. %. The pH of the aqueous solution may be adjusted by addition of sulfuric acid or sodium hydroxide.

The copper foil exiting the last treater 28.4 is thus coated with the three layers 16, 18 and 20, forming the present surface treated copper foil 10.

Before being rolled on the receiving drum 34, the surface treated copper foil 12 is dried in a drying tunnel 40, typically for about 15, 20 or 30 s, or greater.

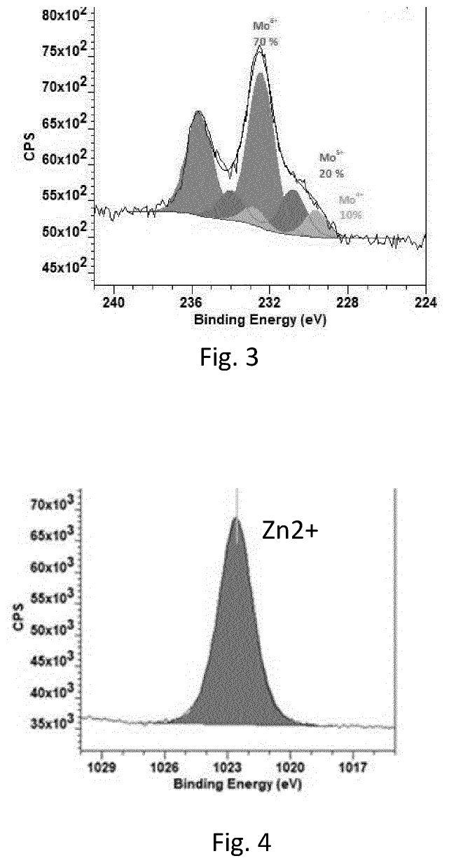

It may be noted here that FIGS. 3 and 4 support the fact that the first passivation layer comprises oxides of zinc and molybdenum. In these first tests the following oxidation states have been observed Zn2+, Mo4+, Mo5+ and Mo6+.

### Examples

A number of examples and counter-examples will now be discussed hereinbelow.

In all of the examples and counter examples, the initial copper foil, to be surface treated, is an electrolytic copper foil produced to have a thickness of 18 μm with the use of a titanium electrolytic drum, a cathode and an insoluble anode, and a cupric sulfate electrolyte. The surface roughness of the as produced electrolytic copper foil was <0.7 μm Rz JIS on both sides.

Examples A1, A2 and A3 relate to surface treated copper foils according to the present process. The first bath 22 comprised 4.0 g/L of Mo and 2.6 g/L of Zn. Regarding example A1, the deposition was carried with at a current density of 0.4 A·dm⁻² at the first anode and 1.2 A·dm⁻² at the second anode, to achieve a specific Mo+Zn mass of 20 mg/m². The current density were adapted for examples A2 and A3 to achieve a specific Mo+Zn mass of 25 mg/m² and 15 mg/m², respectively. The speed of the copper foil through the baths was between 10 and 20 m/min.

The second bath 24 contained 2 g/L of Cr. Deposition was carried with one electrode at a current density of 3.5 A·dm⁻².

The third bath 26 contained 2 wt. % aminosilane as coupling agent.

### <Test Procedures>

To characterize the obtained surface treated copper foils, several tests were performed on the exemplary foils. These tests are generally known in the art and are only briefly presented below.

### Peel Test

The copper foil is laminated at 200 C for 2 hours on a resin substrate, namely a PPE blend resin substrate such as e.g. resin Megtron 6. The peel strength is measured at 90°. The test was carried out according to IPC-TM-650 Method 2.4.8.5.

### Roughness Measurements

The roughness Rz JIS is measured by means of a perthometer in accordance with IPC-TM-650 Method 2.2.17.

The roughness of the surface treated copper foil is measured, for the treatment layer, from the exposed surface of the treatment layer, i.e. the free side 21 of the coupling agent layer 20 opposite the second passivation layer 18.

### SDR—Surface Development Ratio

SDR, or developed interfacial area ratio, expresses the percentage of the definition area's additional surface area contributed by the texture as compared to the planar definition area. The SDR of a completely flat surface is 0. Where a surface has any peak or slope, its SDR value becomes larger.

SDR parameter is measured by contactless measurement, and may be measured using non-contact three-dimensional white light interferometry or non-contact three-dimensional laser interferometry.

Independently from the kind of light used for the measurement (either white light or a laser source), the principle is to divide a light beam in two paths, directing one to a reference mirror and the other one to the sample surface. This measurement beam travel different distances depending on the surface profile. The two waveforms are then recombined and create specific interference patterns depending on their phase difference. Those patterns are analyzed to calculate the height of the sample at each point (pixel) scanned. Roughness parameters such as SDR are then calculated from this 3D profile.

The light source (laser or white light) might be of any kind conventionally used in the field of surface roughness measurement, and the laser may present any desirable wavelength, such as e.g. 408 nm or 658 nm.

In the context of the disclosure, and for the examples and comparative examples, SDR was measured with a 3D laser scanning microscope, namely model Nanoview 3D Surface Profilometer NV2700 using a white light as the light source.

### Thermal Resistance

Thermal resistance is measured via the so-called blistering test. The result indicates the highest temperature at which no blister nor delamination is observed on the copper-clad laminates.

### Chemical Resistance

Chemical resistance is evaluated via the drop of Peel Strength measured after HCl test. The surface treated copper foil is laminated on a resin and track having a width of 1.5 mm are formed. The peel strength is measured before and after dipping in 12% HCl solution during 30 minutes.

### Insertion Loss Measurements

Insertion Loss measurements conducted from 10 MHz to 67 GHz made on PNA E8361C on microstrip PCB design using following characteristics: Microstrip design on EM528 material (Dk=3.5); Copper thickness: 1.8 MIL-18 μm; Track width: 0.47 μm; dielectric thickness: 8 MIL; Impedance=50Ω; No soldermask; No plating finishing; Track length: 20 cm; Connectors ELF-67-002.

### Comparative Examples

A number of comparative examples were prepared starting from the same low roughness 18 μm copper foil used for examples A1-A3.

All comparative examples were surface treated to form a treatment layer including a first passivation layer, a second chrome oxide layer and an aminosilane layer. In some of the counter examples however, the surface treatment includes a nodule layer, on which the three layers are then deposited.

Comparative Example B. The copper foil was treated with nodular treatment, followed by first layer with standard Zn/Cr oxides passivation, followed by a second layer of chromium oxide and then silane coupling layer.

Nodular treatment is deposited in a copper sulfate bath ([Cu]=2-15 g/L; [H2SO4]=30-100 g/L; current density=15−30 A/dm²) to provide adhesion properties by mechanical anchoring.

Comparative Example C. The copper foil was treated with nodular treatment, followed by first layer with metallic Ni passivation (i.e. not oxides) deposited in an Ni—P bath. The second layer of chromium oxide and silane coupling layer where then deposited on the Ni layer.

comparative Example D. The copper foil was treated without nodular treatment, followed by first layer of Mo and Zn oxides in a bath corresponding to example A, however with a too high specific mass of 60 mg/m2. A second layer of chromium oxide a silane coupling layer where then deposited thereon.

Comparative Example F. The copper foil was treated without nodular treatment, but with first layer with metallic Ni passivation (not oxides), followed by a second layer of chromium oxide and then silane coupling layer.

The properties of the various surface treated copper foils are summarized in Table 1. Roughness Rz and SDR in table 1 are those of the free side of the treatment layer.

Foils of examples A-F were submitted to the series of test, the results of which are summarized in table 2.

TABLE 1

| | | First layer | First layer content |
|---|---|---|---|
| Foil | Nodular treatment | Passivation | mg/m2 |
| A1 | No | Zn + Mo oxides | 20 |
| A2 | No | Zn + Mo oxides | 25 |
| A3 | No | Zn + Mo oxides | 15 |
| B | Yes | Zn + Cr oxides | 20 |
| C | Yes | Ni | 30 |
| D | No | Zn + Mo oxides | 60 |
| F | No | Ni | 30 |
| G | No | Zn + Mo oxides | 4 |

TABLE 2

| | | | PS on | HCl | Blistering | Insertion loss |
|---|---|---|---|---|---|---|
| | Rz JIS | SDR | PPE | Loss | Test | @ 30 GHz |
| Foil | μm | % | N/mm | % | ° C. | dB |
| A1 | 0.5 | 0.1 | 0.5 | <10 | 275 | −10.39 |
| A2 | 0.5 | 0.1 | 0.5 | <10 | 275 | −10.39 |
| A3 | 0.5 | 0.1 | 0.5 | <10 | 275 | −10.39 |
| B | 0.5 | 0.8 | 0.5 | <10 | 260 | −11.08 |
| C | 0.5 | 0.8 | 0.5 | <10 | 290 | −11.75 |
| D | 0.5 | 0.1 | 0.5 | 70 | 280 | −10.45 |
| F | 0.5 | 0.1 | 0.5 | <10 | 280 | −12.46 |
| G | 0.5 | 0.1 | 0.3 | <10 | 270 | not measured |

Surface treated copper foils according to the present disclosure, i.e. examples A1-A3, are treated with a non-metallic first layer of Zn and Mo oxides. They have a very smooth treated side and excellent test results: good PS (0.5 N/mm), low HCL loss (less than 10%), high heat resistance (up to 275° C.) and the lowest values of insertion loss.

The following comments can be made with respect to the comparative examples.

The inventive surface treated foils of examples A provide similar roughness Rz parameters compared to foils with nodular treatment (B and C), but with significantly lower developed interfacial area ratio (SDR).

The inventive foils of example A provide similar adhesion on PPE/PPO as measured on foils with nodular treatment (B and C). However, when the amount of Zn and Mo is too low (comparative example G), adhesion on PPE/PPO is not sufficient.

The inventive foils of example A provide high chemical resistance, corresponding to a PS drop<10% after HCl test as observed on foils with nodular treatment (B and C), thanks to a moderate deposition of passivation content (Case D).

The inventive foils of example A provide better thermal resistance (up to 10-20° C.) compared to a foil with nodular treatment and non-metallic passivation (B and C), and similar to a foil without nodular treatment but with metallic passivation (F).

The inventive foils of example A allow improving the signal integrity at high frequencies compared to foils with nodular treatment (B and C) and compared to foils with metallic passivation (C and F).

In summary, only the inventive foils of examples A1-A3, which relies on a low roughness basis foil, nodule free treatment and non-metallic passivation, allows to provide significative improvement on signal integrity meet all requirements for use on HF circuits, namely low roughness, good thermal and chemical resistance, good peel strength and low transmission loss.

1. A surface treated copper foil for a High-Frequency circuit, the copper foil comprising two opposite sides, wherein a first side is coated with a treatment layer comprising, in this order:
a first layer comprising oxides of Mo and of Zn deposited on said first side, wherein said first layer is free of Ni;
a second layer of Cr oxide; and
a third layer being a coupling agent layer;
wherein the first layer comprises the oxides of Mo and of Zn in a quantity of between 5 and 30 mg/m² calculated as Mo and Zn;
wherein said treatment layer has a roughness Rz JIS of 0.7 μm or less; and
wherein said first side is free of roughening treatment.

2. The surface treated copper foil according to claim 1, wherein a weight ratio of Mo to Zn in said first layer is between 0.3 and 1.5.

3. The surface treated copper foil according to claim 1, wherein the first layer comprises more than 80 wt. % of oxides of Mo and of Zn.

4. The surface treated copper foil according to claim 1, wherein the coupling agent layer comprises a functionalized silane coupling agent.

5. The surface treated copper foil according to claim 4, wherein the third layer comprises between 0.5 and 5 mg/m² of coupling agent calculated as Si.

6. The surface treated copper foil according to claim 1, wherein said copper foil has a thickness in the range of 9 to 70 μm.

7. The surface treated copper foil according to claim 1, wherein the treatment layer has a roughness Rz JIS of 0.7, 0.6, 0.5 or 0.4 μm.

8. The surface treated copper foil according to claim 1, wherein the treatment layer has a SDR of 0.3% or less.

9. The surface treated copper foil according to claim 1, wherein a second side of the copper foil, opposite the first side with the treatment layer, has a roughness Rz JIS of 0.7 μm or less.

10. The surface treated copper foil according to claim 1, wherein said copper foil is an electrodeposited copper foil.

11. The surface treated copper foil according to claim 1, wherein said first side is an electrolyte side of said copper foil.

12. The surface treated copper foil according to claim 1, wherein the second layer comprises the Cr oxides in a quantity of between 4 and 10 mg/m² calculated as Cr.

13. A method of treating a copper foil comprising:
providing a copper foil having two opposite sides;
coating a first side of the copper foil with a treatment layer, said coating comprising:
in a first bath, electrodepositing a first layer of oxides of Zn and of Mo, said first bath comprising between 1.5 and 7 g/L of Mo and between 1 and 5 g/L of Zn, the first bath being free of Ni;
in a second bath, electrodepositing a second layer of Cr oxide over said first layer;
in a third bath, forming a third layer being a coupling agent layer over said second layer.

14. (canceled)

15. (canceled)

16. The method according to claim 13, wherein said electrodepositing in said first bath is carried out using two distinct anodes applying different current densities in the range of 0.2 to 1.4 A/dm².

17. The method according to claim 13, wherein said electrodepositing in said first bath is carried out such that said first layer comprises the oxides of Mo and of Zn in a quantity of between 5 and 30 mg/m² calculated as Mo and Zn.

18. The method according to claim 13, wherein the second bath comprises between 0.5 and 4 g/L of Cr.

19. (canceled)

20. The method according to claim 13, wherein said electrodepositing in said second bath is carried out such that said second layer comprises the oxides of Cr in a quantity of between 4 and 10 mg/m² calculated as Cr.

21. The method according to claim 13, wherein the third bath comprises a functionalized silane coupling agent at a concentration between 0.5 and 5 wt. %.

22. (canceled)

23. (canceled)

24. A copper clad laminate comprising a surface treated copper foil according to claim 1 laminated onto a substrate at 200° C. for 2 h, wherein the copper foil has a peel strength superior or equal to 0.40 N/mm; a peel strength drop of 10% or less after a HCl test and is able to resist a blistering test at a temperature of 270° C. or more.

25. The method according to claim 21, wherein said functionalized silane coupling agent comprises an aminosilane, an epoxy-silane, vinyl-silane, methacrylate silane, or a mixture thereof.
